(19) United States
(12) Patent Application Publication
(10) Pub. No.: US 2025/0372192 A1
(43) Pub. Date: Dec. 4, 2025

(54) STORAGE DEVICE, METHOD OF OPERATING THE STORAGE DEVICE, AND MEMORY SYSTEM INCLUDING THE STORAGE DEVICE

(71) Applicant: Samsung Electronics Co., Ltd., Suwon-si (KR)

(72) Inventors: Insang CHO, Suwon-si (KR); Changhyun JOO, Suwon-si (KR); Wookghee HAHN, Suwon-si (KR)

(73) Assignee: Samsung Electronics Co., Ltd., Suwon-si (KR)

(21) Appl. No.: 19/013,557

(22) Filed: Jan. 8, 2025

(30) Foreign Application Priority Data
Jun. 4, 2024 (KR) 10-2024-0073183

(51) Int. Cl. G11C 29/56

(52) U.S. Cl. CPC G11C 29/56016; G11C 29/56012; G11C 2029/5602

(57) ABSTRACT

A storage device may include an external NAND control (ENC) circuit and a nonvolatile memory device. The ENC circuit may include a deserializer configured to deserialize data received from an external device, a buffer memory configured to store the data, and a data loader configured to generate a control signal based on the data. The nonvolatile memory device may include a memory cell array, a voltage generator, a row decoder, and a page buffer. The data may include control information associated with implementing a hardware algorithm.

### CROSS-REFERENCE TO RELATED APPLICATION

This application is based on and claims priority under 35 U.S.C. § 119 to Korean Patent Application No. 10-2024-0073183, filed on Jun. 4, 2024, in the Korean Intellectual Property Office, the disclosure of which is incorporated by reference herein in its entirety.

### BACKGROUND

Various example embodiments relate, in general, to a storage device, and more particularly, to a storage device including an external NAND control circuit, a method of operating the storage device, and/or a memory system including the storage device.

Flash memory is a nonvolatile memory device capable of retaining stored data even when power thereto is turned off. Recently, storage devices including flash memory such as one or more of an embedded multi-media card (eMMC), a universal flash storage (UFS), a solid state drive (SSD), and memory cards have been widely used, and such storage devices may be effectively used for storing or transferring large amounts of data. In the process of increasing the storage capacity of such devices, the complexity of NAND flash memory cells increases, leading to an increase in the number of control algorithms and the number of control signals. Alternatively or additionally, the number of options for verifying the characteristics of memory cells has also exponentially increased.

Although it is necessary or desirable to find an improved or optimal algorithm that matches the characteristics of memory cells, there is a limit to predicting the characteristics of memory cells during the development process, and when unexpected characteristics are discovered, the development time may increase because modifications to the algorithm are necessary. Alternatively or additionally, when developing NAND flash hardware in the related art, multiple operation algorithms are individually implemented and selectively tested to determine which algorithm will be used. However, this approach requires remaking of chips to test newly implemented algorithms. Therefore, significant production time and costs are needed for manufacturing chips. Alternatively or additionally, algorithms that can be evaluated are limited, and thus, more effective algorithms may not be used.

### SUMMARY

Provided are a storage device including an external NAND control circuit, and/or a method of operating the storage device.

Additional aspects will be set forth in part in the description which follows and, in part, will be apparent from the description, or may be learned by practice of various example embodiments of the disclosure.

According to an aspect of the disclosure, a storage device includes an external NAND control (ENC) circuit and a nonvolatile memory device. The ENC circuit includes a deserializer configured to deserialize data received from an external device, a buffer memory configured to store the data, and a data loader configured to generate a control signal based on the data. The nonvolatile memory device includes a memory cell array, a voltage generator, a row decoder, and a page buffer. The data may include control information associated with implementing a hardware algorithm.

Alternatively or additionally, there is provided a method of operating a storage device including an external NAND control (ENC) circuit configured to receive data from an external device, and a nonvolatile memory device. The method includes receiving data from the external device, dividing the received data into a plurality of channels, storing the divided data in a buffer memory, and acquiring memory cell characteristics by generating a control signal based on the divided data and applying the control signal to the nonvolatile memory device. The data includes control information associated with implementing a hardware algorithm.

Alternatively or additionally according to various example embodiments, a memory system includes an external device and a storage device. The external device is configured to provide the storage device with data for identifying memory cell characteristics of the storage device. The storage device includes an extended NAND control (ENC) circuit and a nonvolatile memory device. The ENC circuit includes a deserializer configured to deserialize the data received from the external device, a buffer memory for storing the data, and a data loader configured to generate a control signal based on the data. The nonvolatile memory device includes a memory cell array. The data includes control information for implementing a hardware algorithm.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a diagram illustrating an example of a memory system according to various example embodiments;

FIG. 2 is a block diagram illustrating a storage device shown in FIG. 1 according to various example embodiments;

FIG. 3 is a block diagram illustrating an external NAND control (ENC) circuit according to various example embodiments;

FIG. 4 is a perspective view illustrating an implementation example of a memory block shown in FIG. 2, according to various example embodiments;

FIG. 5 is a circuit diagram illustrating another example of a memory block according to various example embodiments;

FIG. 6 is a diagram illustrating an example of a serializer/deserializer (SERDES) interface according to various example embodiments;

FIG. 7 is a diagram illustrating an example of static random access memory (SRAM) according to various example embodiments;

FIGS. 8A and 8B are diagrams respectively illustrating an example of a first operation mode and an example of a second operation mode, according to embodiments;

FIG. 9 is a diagram illustrating an example of a data loader according to various example embodiments;

FIG. 10 is a diagram illustrating an example of the flow of development according to various example embodiments; and

FIG. 11 is a block diagram illustrating an example of applying memory devices to a solid state drive (SSD) system according to embodiments.

### DETAILED DESCRIPTION

Reference will now be made in detail to embodiments, examples of which are illustrated in the accompanying drawings, wherein like reference numerals refer to like elements throughout. In this regard, various embodiments may have different forms and should not be construed as being limited to the descriptions set forth herein. Accordingly, example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terms used in embodiments are general terms currently widely used in the art in consideration of functions regarding the disclosure, but the terms may vary according to the intention of those of ordinary skill in the art, precedents, or new technology in the art. Also, some terms may be arbitrarily selected by the applicant, and in this case, the meaning of the selected terms will be described in the detailed description of the disclosure. Thus, the terms used herein should not be construed based on only the names of the terms but should be construed based on the meaning of the terms together with the description throughout the disclosure.

In the following descriptions of embodiments, when a portion or element is referred to as being connected to another portion or element, the portion or element may be directly connected to the other portion or element, or may be electrically connected to the other portion or elements with intervening portions or elements being therebetween. It will be further understood that the terms “comprises” and/or “comprising” used herein specify the presence of stated features or elements, but do not preclude the presence or addition of one or more other features or elements.

In the following descriptions of embodiments, expressions or terms such as “constituted by,” “formed by,” “include,” “comprise,” “including,” and “comprising” should not be construed as always including all specified elements, processes, or operations, but may be construed as not including some of the specified elements, processes, or operations, or further including other elements, processes, or operations.

The following descriptions of embodiments should not be construed as limiting the scope of the disclosure, and modifications or changes that could be easily made from the embodiments by those of ordinary skill in the art should be construed as being included in the scope of the inventive concept. Hereinafter, embodiments will be described with reference to the accompanying drawings. In the drawings, like reference numerals denote like elements, and repeated descriptions thereof are omitted.

Hereinafter, embodiments will be described with reference to the accompanying drawings.

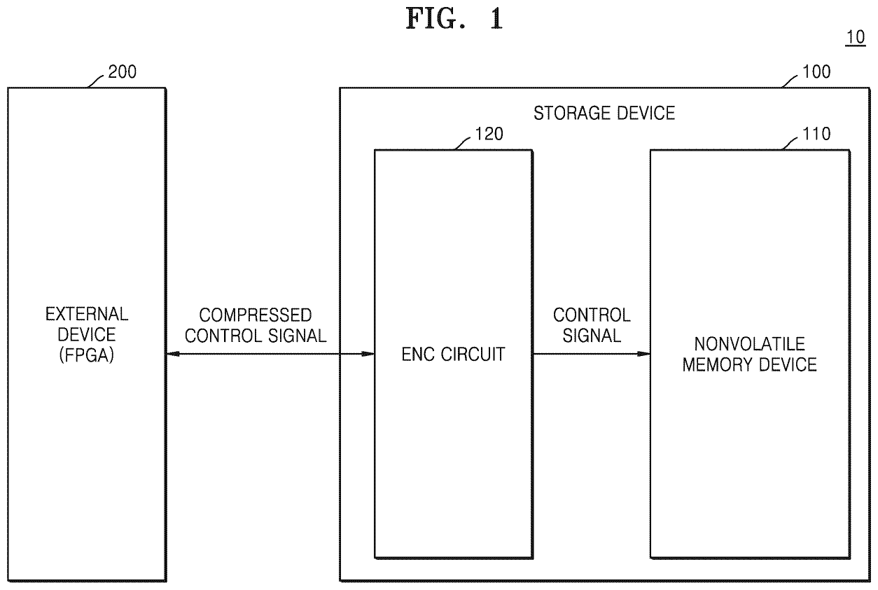

FIG. 1 illustrates an example of a memory system 10 according to various example embodiments.

Referring to FIG. 1, the memory system 10 may include a storage device 100 and an external device 200. The external device 200 may correspond to a field programmable gate array (FPGA). The storage device 100 may include a nonvolatile memory device 110 and an external NAND control (ENC) circuit 120.

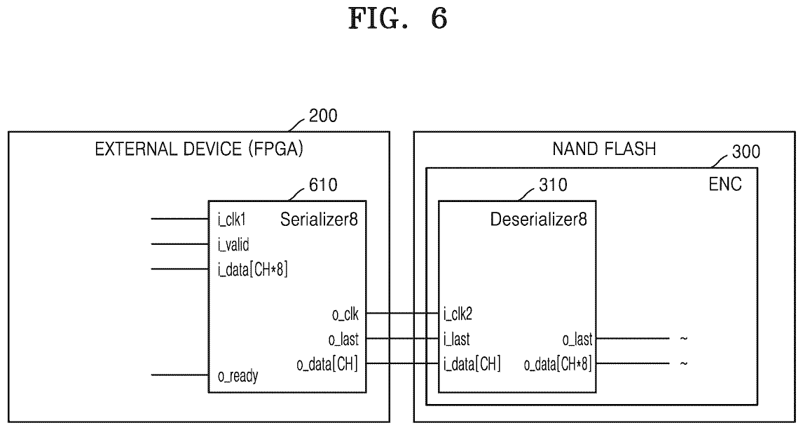

According to various example embodiments, the external device 200 may transmit control signals to the storage device 100. For example, the external device 200 may convert control signals into a stream, e.g., a serial stream of bits, by using a serializer (for example, refer to a serializer 610 shown in FIG. 6), and may provide the stream to the storage device 100. According to various example embodiments, control signals may refer to signals for implementing a new algorithm for testing characteristics of memory cells of the storage device 100 in terms of hardware. For example, the algorithm may at least include information about a sequence of applying word line voltages and/or information about the degree of variation in word line voltage (for example, a slope or a step or an instantaneous slope of a word line voltage).

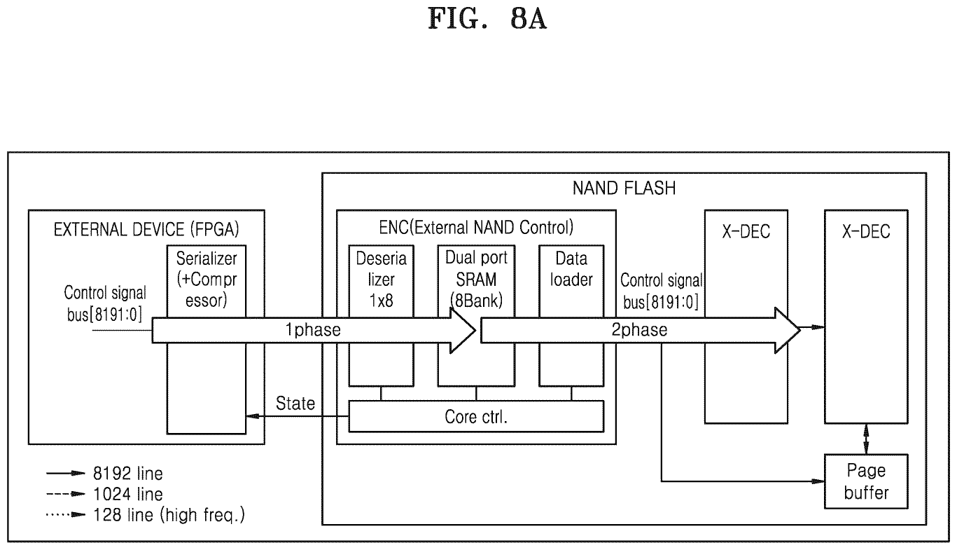

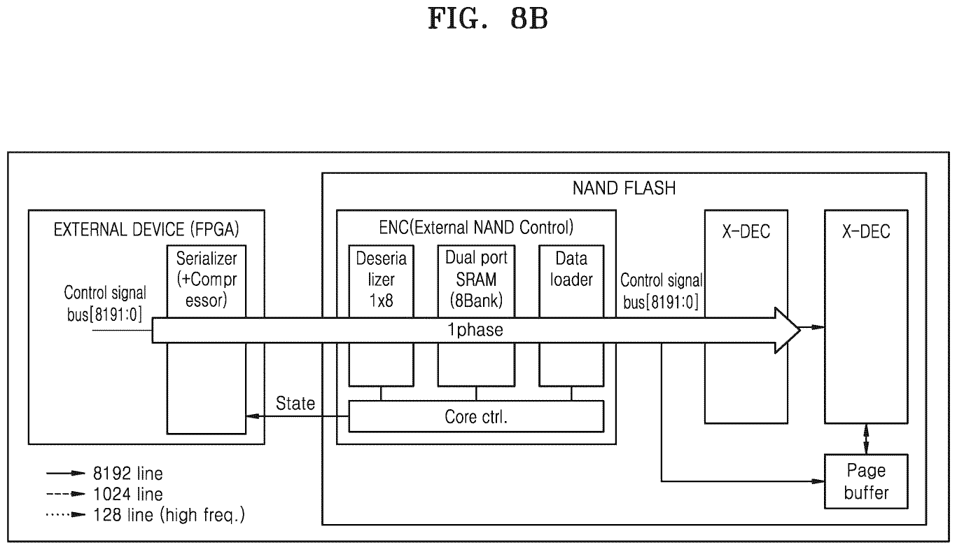

According to various example embodiments, the external device 200 may provide the storage device 100 with information indicating an operation mode based on an algorithm. For example, the operation mode may correspond to either a first operation mode or a second operation mode. The first operation mode may correspond to a case in which the operation frequency of the storage device 100 exceeds a threshold frequency according to control signals of an algorithm to be tested. The second operation mode may correspond to a case in which the operation frequency of the storage device 100 is below the threshold frequency according to the control signals of an algorithm to be tested. The first and second operation modes are further described below with reference to FIGS. 8A and FIG. 8B.

According to various example embodiments, the nonvolatile memory device 110 may write or program/erase data received in response to a write command into a memory cell array and/or may read out data stored at an address in response to a read command.

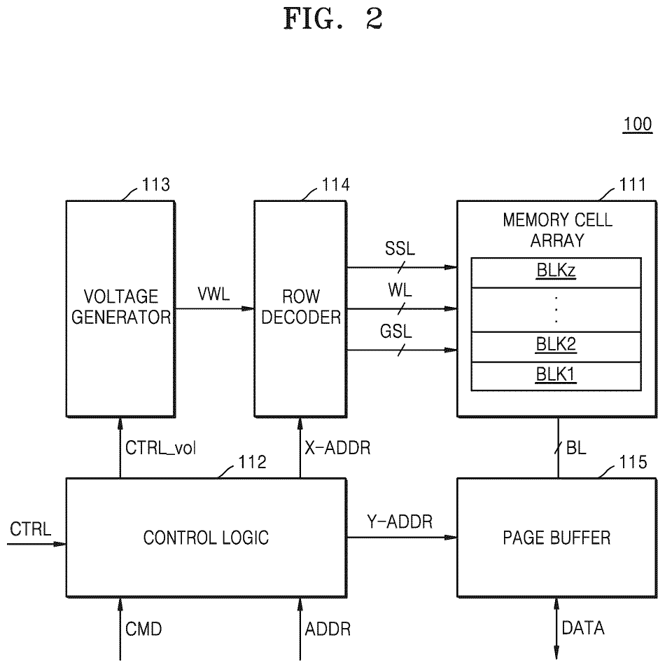

According to various example embodiments, the ENC circuit 120 may generate a control signal to control the nonvolatile memory device 110. The ENC circuit 120 may identify cell characteristics of the memory cell array (refer to a memory cell array 111 shown in FIG. 2) by applying a control signal to the nonvolatile memory device 110. In this case, the ENC circuit 120 may receive control signals from the external device 200 and provide the control signals to the nonvolatile memory device 110, and thus, various algorithms may be prepared without limitations based on control signals generated by the ENC circuit 120. For example, the control signals may be for implementing new algorithms.

For example, according to various example embodiments, the ENC circuit 120 may have improved approaches to testing characteristics of memory cells of the nonvolatile memory device 110 in various manners by receiving control signals for implementing new algorithms from the external device 200 and generating the control signals. In related art, however, a controller may only control the nonvolatile memory device 110 according to a predetermined algorithm and is unable to test characteristics of the memory cells of the nonvolatile memory device 110 for new algorithms.

FIG. 2 is a block diagram illustrating a storage device 100 according to various example embodiments.

Referring to FIG. 2, the storage device 100 may include a nonvolatile memory device 110 (refer to FIG. 1) and an ENC circuit 120 (refer to FIG. 1). The nonvolatile memory device 110 may include a memory cell array 111, control logic 112, a voltage generator 113, a row decoder 114, and a page buffer 115. Although not shown in FIG. 2, the storage device 100 may further include a data input/output circuit or an input/output interface. Additionally or alternatively, the storage device 100 may include a redundancy checker and/or an error-correcting checker circuit.

The memory cell array 111 may include a plurality of memory cells and may be connected to word lines WL, string selection lines SSL, ground selection lines GSL, and bit lines BL. For example, the memory cell array 111 may be connected to the row decoder 114 through the word lines WL, the string selection lines SSL, and the ground selection lines GSL, and may be connected to the page buffer 115 through the bit lines BL.

The memory cell array 111 may include a plurality of memory blocks BLK1 to BLKz. For example, each of the memory blocks BLK1 to BLKz may have a 3D structure (or vertical structure); example embodiments are not limited thereto. For example, each of the memory blocks BLK1 to BLKz may include structures extending in first to third directions. For example, each of the memory blocks BLK1 to BLKz may include a plurality of NAND strings (hereinafter referred to as “strings”) extending in the third direction. In this case, the strings may be provided apart from each other by a certain distance in the first and second directions. The memory blocks BLK1 to BLKz may be selected by the row decoder 114. For example, the row decoder 114 may select a memory block corresponding to a memory block address from among the memory blocks BLK1 to BLKz.

In some examples, each or at least some of the memory cells included in the memory cell array 111 may store at least two bits. For example, each or at least some of the memory cells may be a multi-level cell (MLC) storing 2-bit data. Alternatively or additionally, each or at least some of the memory cells may be a triple-level cell (TLC) storing 3-bit data. Alternatively or additionally, each or at least some of the memory cells may be a quad-level cell (QLC) storing 4-bit data. However, example embodiments are not limited thereto. For example, some memory cells included in the memory cell array 111 may each be a single-level cell (SLC) storing 1-bit data, and the rest of the memory cells included in the memory cell array 111 may each be an MLC.

The memory blocks BLK1 to BLKz may include at least one selected from an SLC block including SLCs, an MLC block including MLCs, a TLC block including TLCs, and a QLC block including QLCs. Among the memory blocks BLK1 to BLKz included in the memory cell array 111, some memory blocks may be SLC blocks, and the other memory blocks may be MLC blocks or TLC blocks.

When an erase voltage is applied to the memory cell array 111, the some of the memory cells may be erased and enter into an erased state, and when a program pulse or program voltage is applied to the memory cell array 111, some of the memory cells may be programmed and enter into a programmed state. In this case, each of the memory cells may have an erased state or at least one programmed state that is distinguished by a threshold voltage Vth.

After the memory cells switch from the erased state to a programmed state in response to a program pulse corresponding to the programmed state, the memory cells may be divided into a plurality of cell groups according to the speed of programming based on a Gaussian distribution of threshold voltages of the memory cells. For example, when the memory cells are QLCs each configured to be programmed with 4 bits, the memory cells may each have an erased state or one of first to fifteenth programmed states.

The control logic 112 may output various control signals for writing data to the memory cell array 111 and/or for reading data from the memory cell array 111 based on a command CMD, an address ADDR, and a control signal CTRL received from a memory controller. Thus, the control logic 112 may generally control various operations in the nonvolatile memory device 110.

Various control signals output from the control logic 112 may be provided to the voltage generator 113, the row decoder 114, and the page buffer 115. The control logic 112 may provide a voltage control signal CTRL_vol to the voltage generator 113. In various example embodiments, the control logic 112 may generate a voltage control signal CTRL_vol to control generation of a program pulse and a verification voltage that are to be provided to the memory cell array 111 for writing data to the memory cells.

The control logic 112 may control the voltage generator 113 such that the voltage generator 113 generates at least one verification voltage and at least one program pulse in each program loop. In addition, the control logic 112 may control the voltage generator 113 such that the voltage generator 113 generates a program pulse having a level varying as the number of program loops increases. For example, the control logic 112 may control the voltage generator 113 such that the voltage generator 113 generates a program pulse having a level increased by a step voltage as the number of program loops increases, e.g., by a constant amount per step, or by a variable amount per step.

The voltage generator 113 may generate various types of voltages to perform program, read, and erase operations on the memory cell array 111 based on a voltage control signal CTRL_vol. For example, the voltage generator 113 may generate word line voltages VWL, program pulses and verification voltages.

The row decoder 114 may select some word lines WL from among the word lines WL in response to a row address X-ADDR received from the control logic 112. For example, in a program operation, the row decoder 114 may provide a program pulse to the selected word lines WL. In some examples, the row decoder 114 may select some string selection lines SSL from among the string selection lines SSL or some ground selection lines GSL from among the ground selection lines GSL in response to a row address X-ADDR received from the control logic 112.

The page buffer 115 may be connected to the memory cell array 111 through the bit lines BL and may select some bit lines BL from among the bit lines BL in response to a column address Y-ADDR received from the control logic 112. In a read operation, the page buffer 115 may operate as a sense amplifier to sense data DATA stored in the memory cell array 111. Furthermore, in a program operation, the page buffer 115 may operate as a write driver such that data DATA to be stored in the memory cell array 111 may be input to the page buffer 115. The page buffer 115 may store data DATA that is read from the memory cell array 111 or data DATA that is to be written to the memory cell array 111.

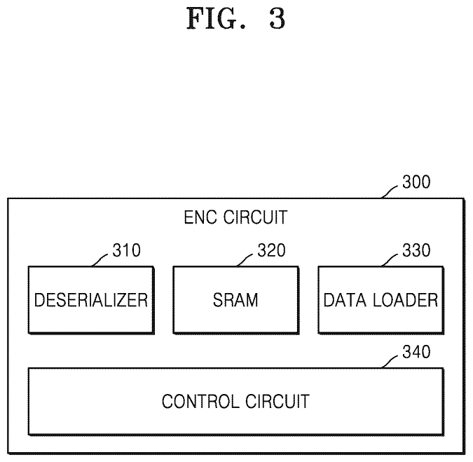

FIG. 3 is a block diagram illustrating an ENC circuit 300 according to various example embodiments.

Referring to FIG. 3, the ENC circuit 300 may correspond to the ENC circuit 120 shown in FIG. 1. The ENC circuit 300 may include a deserializer 310, static random access memory (SRAM) 320 having multiple ports, a data loader 330, and a control circuit 340.

According to various example embodiments, the deserializer 310 may receive a single data stream, e.g., a data stream of bits, from an external device (for example, the external device 200 shown in FIG. 1A) and may divide the received data stream into a plurality of streams. For example, the deserializer 310 may divide received data. When the deserializer 310 is an 8:1 deserializer, the deserializer 310 may divide the received data into eight streams. The deserializer 310 may reduce the number of physical ports by allowing the external device 200 to transmit data at a relatively high frequency in consideration of whether the operation frequency of the nonvolatile memory device 110 (refer to FIG. FIG. 1) is 12.5 MHz or 25 MHz For example, during an 8:1 operation, 1,024 signals may be transmitted by transmitting 128 signals at a frequency multiplied by 8 to reduce the interface size between the external device 200 and the storage device 100 to one-eighth. The deserializer 310 may provide the SRAM 320 with the streams obtained by dividing the received data.

The SRAM 320 may operate as buffer memory for storing output signals of the deserializer 310. In this case, dual-port SRAM that is operable with different operation frequencies at two ports may be used to operate the deserializer 310 and the nonvolatile memory device 110 at different operation frequencies and thus to improve efficiency. For example, the operation frequency of the deserializer 310 may correspond to a good or an optimal frequency for stable transmission, and the operation frequency of the nonvolatile memory device 110 may correspond to a target frequency of an algorithm of an operation scenario. The SRAM 320 is further described below.

The data loader 330 may generate a control signal. For example, the data loader 330 may receive data and duration information indicating a time period from the SRAM 320 and may generate a control signal based on the data and the duration information. The data loader 330 may provide the same data as a control signal to the nonvolatile memory device 110 for a time period based on the duration information indicating a time period.

The control circuit 340 may control the overall operation of the ENC circuit 300. For example, the control circuit 340 may control the deserializer 310 such that the deserializer 310 divides data into data streams, and the data streams may be stored into the SRAM 320 in the form of an event-based look-up table (LUT) that stores data and duration information. In some example embodiments, when testing cell characteristics of the nonvolatile memory device 110, the control circuit 340 may control the data loader 330 to search the event-based LUT stored in the SRAM 320 for reading out data corresponding to a control signal and duration information indicating a time period during which the same control signal is repeated, and provide the data and the duration information to the data loader 330. The control circuit 340 may control the data loader 330 to repeatedly generate a control signal of data read out from the SRAM 320 for a time period indicated by information read out from the SRAM 320.

Any of the blocks in FIG. 3 may communicate with any other of the blocks in FIG. 3, for example in one or more of a one-to-one, one-to-many, or broadcast manner, through a wired and/or wireless bus, to exchange information, such as but not limited to data and/or commands, in formats such as but not limited to digital and/or analog formats, in a serial and/or a parallel manner.

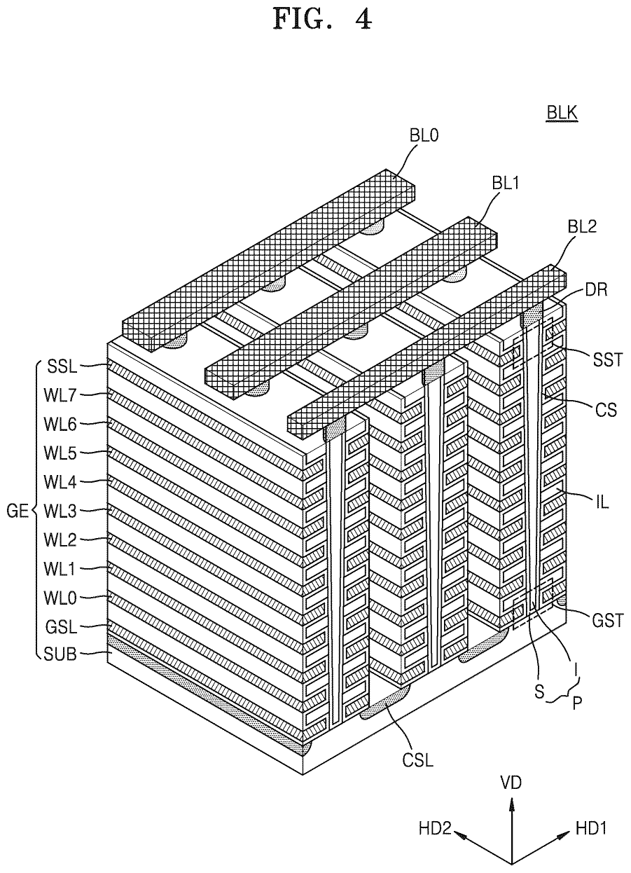

FIG. 4 is a perspective diagram illustrating an implementation example of a memory block BLK shown in FIG. 2, according to various example embodiments.

Referring to FIG. 4, the memory block BLK is formed in a direction perpendicular to a substrate SUB. The substrate SUB has a first conductivity type (for example, p type) and includes common source lines CSL extending on the substrate SUB in a second horizontal direction HD2 and doped with a dopant having a second conductivity type (for example, n type). Although not shown in FIG. 4, a plurality of insulating films extending in the second horizontal direction HD2 are sequentially provided in a vertical direction VD on regions of the substrate SUB between adjacent common source lines CSL. The insulating films are apart from each other by a predetermined and/or dynamically determined distance in the vertical direction VD. For example, the insulating films may include an insulating material such as silicon oxide.

On the regions of the substrate SUB between the adjacent common source lines CSL, a plurality of pillars P extending in the vertical direction VD and penetrating the insulating films are sequentially arranged in a first horizontal direction HD1. For example, the pillars P may penetrate the insulating films IL and come into contact with the substrate SUB. For example, a surface layer S of each of the pillars P may include a silicon material of the first conductive type and may function as a channel region. In addition, an inner layer I of each of the pillars P may include an insulating material such as silicon oxide or an air gap.

Charge storage layers CS are provided along exposed surfaces of the insulating films IL, the pillars P, and the substrate SUB on the regions between the adjacent common source lines CSL. The charge storage layers CS may each include a gate insulating layer (referred to as a “tunneling insulating layer”), a charge trap layer, and a blocking insulating layer. For example, the charge storage layers CS may have an oxide-nitride-oxide (ONO) structure. Furthermore, gate electrodes GE such as ground selection lines GSL, string selection lines SSL, and word lines WL1 to WL8 may be provided on exposed surfaces of the charge storage layers CS on the regions between the adjacent common source lines CSL.

Drains or drain contacts DR are respectively provided on the pillars P. For example, the drains or drain contacts DR may include a silicon material doped with a dopant having the second conductivity type. Bit lines BL1 to BL3 extending in the first horizontal direction HD1 and apart from each other by a predetermined distance in the second horizontal direction HD2 are provided on the drains or drain contacts DR.

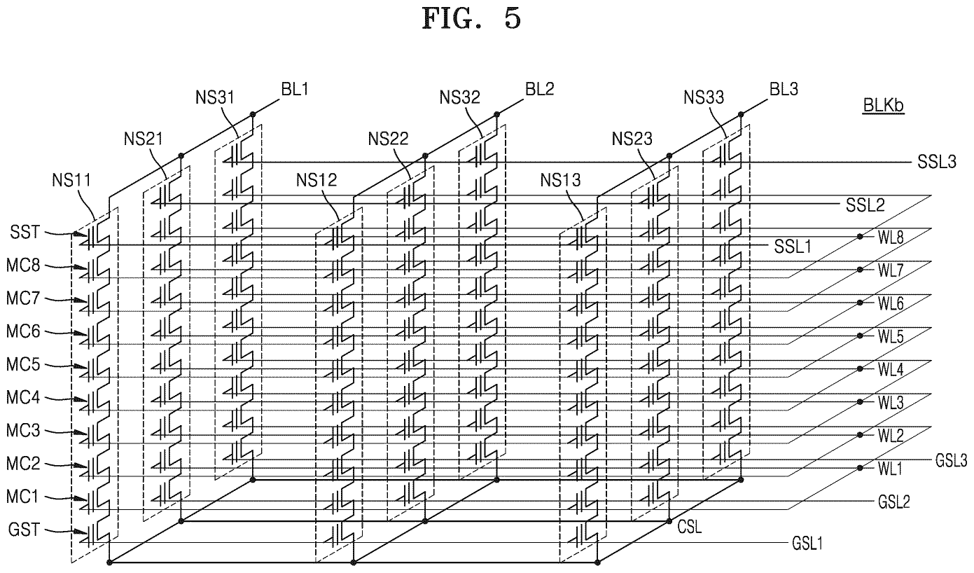

FIG. 5 is a circuit diagram illustrating another example of a memory block according to various example embodiments.

Referring to FIG. 5, a memory block BLKb may be a vertical NAND flash memory. The memory block BLKb may include a plurality of NAND strings NS11 to NS33, a plurality of word lines WL1 to WL8 (for example, first to eighth word lines WL1 to WL8), a plurality of bit lines BL1 to BL3 (for example, first to third bit lines BL1 to BL3), a plurality of ground selection lines GSL1, GSL2, and GSL3, a plurality of string selection lines SSL1 to SSL3 (for example, first to third string selection lines SSL1 to SSL3), and a common source line CSL. The number of NAND strings, the number of word lines, the number of bit lines, the number of ground selection lines, and the number of string selection lines may be variously changed according to various embodiments.

The NAND strings NS11, NS21, and NS31 are provided between the first bit line BL1 and the common source line CSL, the NAND strings NS12, NS22, and NS32 are provided between the second bit line BL2 and the common source line CSL, and the NAND strings NS13, NS23, and NS33 are provided between the third bit line BL3 and the common source line CSL. Each of the NAND strings (for example, the NAND string NS11) may include a string selection transistor SST, a plurality of memory cells MC1 to MC8, and a ground selection transistor GST that are connected in series to each other. Hereinafter, NAND strings may be referred to as strings for ease of illustration.

Strings commonly connected to one bit line may form a column. For example, the strings NS11, NS21, and NS31 commonly connected to the first bit line BL1 may correspond to a first column, the strings NS12, NS22, and NS32 commonly connected to the second bit line BL2 may correspond to a second column, and the strings NS13, NS23, and NS33 commonly connected to the third bit line BL3 may correspond to a third column.

Strings connected to one string selection line may form a row. For example, the strings NS11, NS12, and NS13 connected to the first string selection line SSL1 may correspond to a first row, the strings NS21, NS22, and NS23 connected to the second string selection line SSL2 may correspond to a second row, and the strings NS31, NS32, and NS33 connected to the third string selection line SSL3 may correspond to a third row.

The string selection transistors SST are connected to the string selection lines SSL1 to SSL3. The memory cells MC1 to MC8 are respectively connected to the word lines WL1 to WL8 corresponding to the memory cells MC1 to MC8. The ground selection transistors GST are connected to the ground selection lines GSL1, GSL2, and GSL3. The string selection transistors SST are connected to the bit lines BL1 to BL3 corresponding to the string selection transistors SST, and the ground selection transistors GST are connected to the common source line CSL.

Word lines having the same height (for example, word lines WL1) may be connected to each other, and the string selection lines SSL1 to SSL3 are separate from each other. For example, when memory cells connected to the first word lines WL1 and included in the strings NS11, NS12, and NS13 are programmed, the first word lines WL1 and the first string selection line SSL1 are selected. In various example embodiments, the ground selection lines GSL1, GSL2, and GSL3 may be separate from each other as shown in FIG. 5. In another embodiment, the ground selection lines GSL1, GSL2, and GSL3 may be connected to each other.

FIG. 6 illustrates an example of a serializer/deserializer (SERDES) interface according to various example embodiments.

Referring to FIG. 6, the SERDES interface may include a serializer 610 of an external device 200 and a deserializer 310 of an ENC circuit 300. The external device 200 may correspond to an FPGA; however, example embodiments are not limited thereto.

The serializer 610 of the external device 200 may receive input data according to a first clock i_clk1. For example, the serializer 610 may receive input data in parallel from a number of channels, such as from eight channels, according to the first clock i_clk1. The serializer 610 may determine, based on a validity signal i_valid, whether the input data is valid.

According to various example embodiments, the serializer 610 may receive eight signals in parallel as input data and may serialize and transmit the input data through one channel, e.g., through a single channel. The serializer 610 may transmit the input data to the deserializer 310 according to a second clock o_clk. In this case, the second clock o_clk may be a multiple of the first clock i_clk1. For example, the multiple may correspond to the number of channels from which the serializer 610 receives the input data. Referring to FIG. 6, signals of data input to the serializer 610 are eight times that of data output from the serializer 610, and thus, the second clock o_clk may be eight times the first clock i_clk1. The serializer 610 may synchronize with the deserializer 310 through a sync clock o_last or i_last.

According to various example embodiments, the deserializer 310 may receive data from the serializer 610 according to a third clock i_clk2. In this case, the third clock i_clk2 may be the same as the second clock o_clk that is an output clock of the serializer 610. The deserializer 310 may receive data from the serializer 610 through one channel and divide the received data. For example, the deserializer 310 may divide data received through one signal into eight streams and may output the eight streams in parallel through eight signals.

In example embodiments described above, the serializer 610 serializes data using one channel at an 8:1 ratio, and the deserializer 310 deserializes data at a 1:8 ratio. However, example embodiments are not limited thereto. In various embodiments, the serialization/deserialization ratio of the SERDES interface and the number of channels may be variously adjusted.

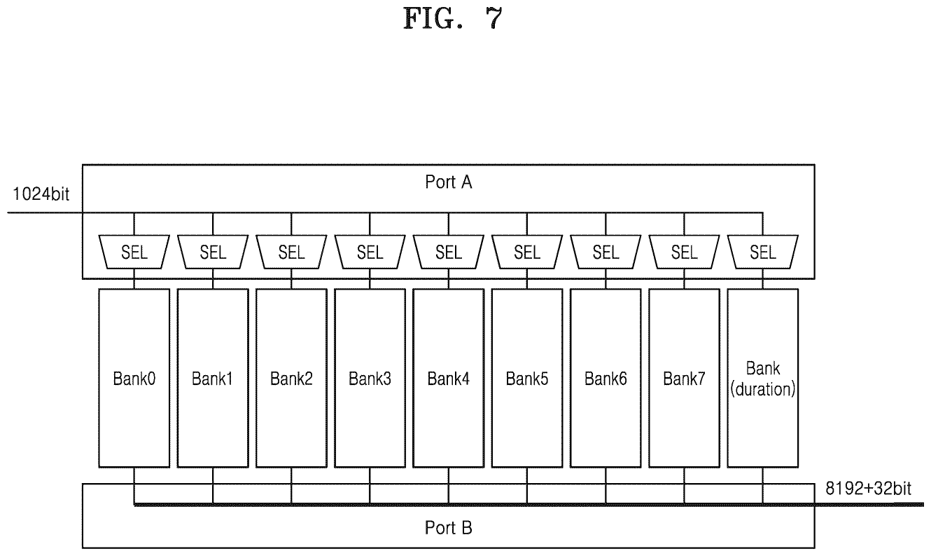

FIG. 7 illustrates an example of the SRAM 320 according to various example embodiments.

Referring to FIG. 7, the SRAM 320 may include a plurality of bank memories. The number of bank memories may be determined based on the number of channels used for parallel transmission by the deserializer 310. Referring also to FIG. 6, the deserializer 310 may deserialize data received through one channel into eight channels and transmit the data to the SRAM 320. In this case, the number of bank memories may be nine by adding one to the number of channels used for parallel transmission. For example, among the bank memories, a first bank memory Bank0 to an eighth bank memory Bank7 may store data output from the eight channels of the deserializer 310. The additional bank memory may store the duration of each event. For example, when the same data is transmitted from a first time point to a second time point, the SRAM 320 may store, in the additional bank memory, information about the length of duration corresponding to the difference between the second time point and the first time point.

According to various example embodiments, the SRAM 320 may correspond to a dual-port memory. For example, a first port Port A may be for receiving an output of the deserializer 310. A second port Port B may be for an output to the data loader 330. According to various example embodiments, the first port Port A may include selectors SEL respectively connected to the bank memories. Thus, the deserializer 310 may access one bank memory at a time through the first port Port A. The SRAM 320 may access the bank memories at one time through the second port Port B to convert a data bandwidth. For example, when the size of each of the bank memories is 1024 bits, the bandwidth of data input through the first port Port A may correspond to 1024 bits, and the bandwidth of data output to the data loader 330 through the second port Port B may be 8192+32 bits. The additional 32 bits may be the output bits of the additional bank memory storing information about the duration of each event.

FIG. 8A illustrates an example of a first operation mode according to various example embodiments, and FIG. 8B illustrates an example of a second operation mode according to various example embodiments.

Referring to FIG. 8A, the memory system 10 may operate based on the first operation mode. The first operation mode may correspond to a case in which the operation frequency of the storage device 100 based on control signals of an algorithm to be tested is greater than a threshold frequency. For example, when an operation frequency based on control signals of an algorithm to be tested is greater than the threshold frequency, the external device 200 may provide operation-mode information indicating the first operation mode to the ENC circuit 120. The external device 200 may provide the control signals of the algorithm to be tested to the ENC circuit 120 during a first phase 1phase in response to the determination of the first operation mode. After all the control signals of the algorithm are provided to the ENC circuit 120 during the first phase 1phase, the ENC circuit 120 may transition to a second phase 2phase.

The ENC circuit 120 may generate control signals using the data loader 330 during the second phase 2phase based on data received and stored in the SRAM 320 during the first phase 1phase. The operation frequency required by or used by the algorithm to be tested is high, and thus, when the ENC circuit 120 generates control signals by receiving data on the control signals in real time from the external device 200, the generation and transmission speed of the control signals may be lower than the operation frequency required by the algorithm. Thus, it may be understood that all data required to or used to execute the algorithm is received during the first phase 1phase.

Referring to FIG. 8B, the memory system 10 may operate based on the second operation mode. The second operation mode may correspond to a case in which the operation frequency of the storage device 100 based on control signals of an algorithm to be tested is less than the threshold frequency. For example, when an operation frequency based on control signals of an algorithm to be tested is less than the threshold frequency, the external device 200 may provide operation-mode information indicating the second operation mode to the ENC circuit 120. In response to the determination of the second operation mode, the external device 200 may provide the control signals in real time to the storage device 100 instead of performing external control by dividing the second operation mode into the first phase 1phase and the second phase 2phase as in the first operation mode. The reason for this may be as follows: the operation frequency required by or used by the algorithm to be tested is not high, and thus, even when the ENC circuit 120 generates control signals by receiving data on the control signals in real time from the external device 200, the operation frequency required by or expected by the algorithm may still be satisfied.

In some example embodiments, as a result of improved testing, sorting of products and/or downgrading of products may be improved. For example, as a result of the methods described above with respect to FIGS. 8A and 8B, certain products may be sorted based on a result of testing. This may improve yield and/or reliability.

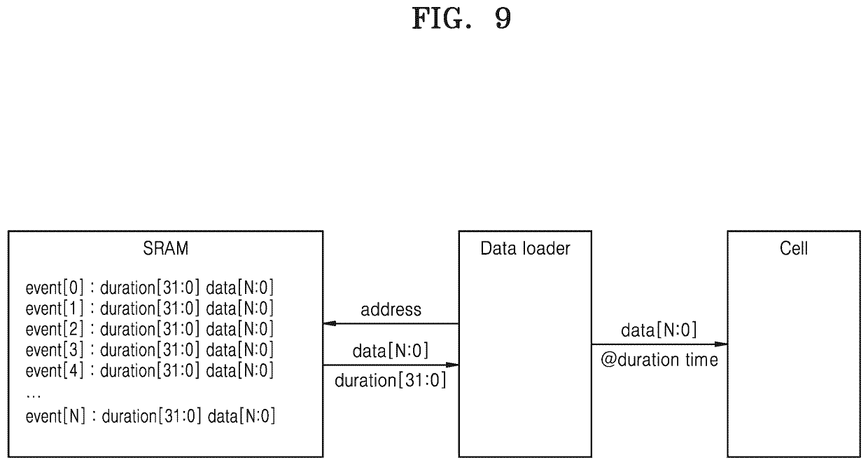

FIG. 9 illustrates an example of the data loader 330 according to various example embodiments.

Referring to FIG. 9, the data loader 330 may provide address information to the SRAM 320. The address information may correspond to information indicating a target address at which writing or reading is to be performed.

According to various example embodiments, the SRAM 320 may store duration information and data for each event. For example, a first event[0] may be an event of providing data[N:0] for a time period indicated by duration[31:0] (duration information). A second event[1] may be an event of providing data[N:0] for a time period indicated by duration[31:0] (duration information).

The data loader 330 may receive duration information and data corresponding to an event from the SRAM 320. For example, the data loader 330 may receive duration[31:0] and data[N:0] corresponding to the first event[0]. The data loader 330 may repeatedly generate a control signal and apply the control signal to the nonvolatile memory device 110, based on the received data[N:0] for a time period corresponding to the duration information (duration[31:0]) of the received first event[0]. Thereafter, the data loader 330 may receive duration[31:0] and data[N:0] corresponding to the second event[1]. The data loader 330 may repeatedly generate a control signal and apply the control signal to the nonvolatile memory device 110, based on the received data[N:0] for a time period corresponding to the duration information (duration[31:0]) of the received second event[1].

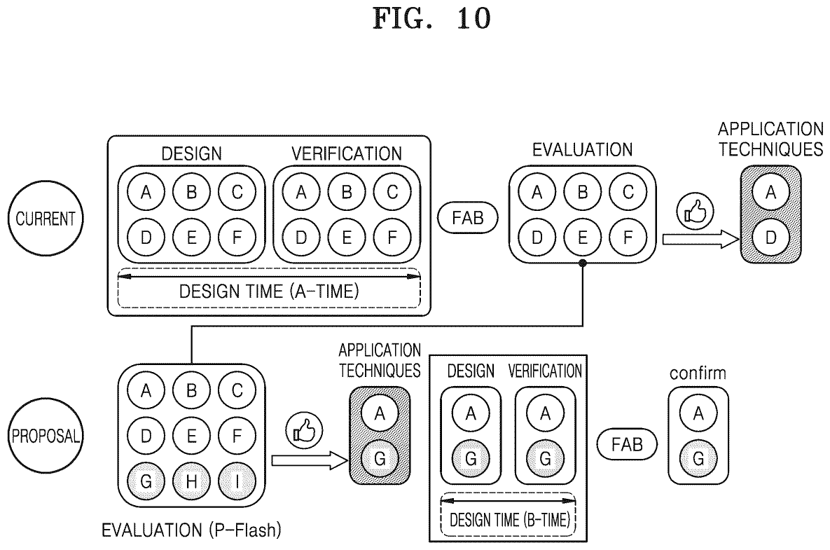

FIG. 10 is a diagram illustrating an example of the flow of development according to various example embodiments.

Referring to FIG. 10, the flow of development in the related art is as follows: a chip including the nonvolatile memory device 110 is fabricated by predicting various algorithms and by implementing and verifying many methods, and after the chip is completely fabricated, evaluation is performed to determine which algorithm is good or optimal and then determine techniques to be used. For example, after designing and verifying algorithms A to F, chips are actually fabricated and evaluated using the algorithms to select those evaluated as good algorithms (for example, algorithms A and D) for mass production. When the storage device 100 does not include the ENC circuit 120 of the variously described example embodiments, as in the related art, the storage device 100 is unable to receive control signals from the external device 200 and to apply the control signals to the nonvolatile memory device 110, and new algorithms may not be applied to the storage device 100 because of a low degree of freedom of a memory controller. Therefore, application of new algorithms (for example, algorithms G to I) may require significant time and high costs for designing and verifying the new algorithms, and newly fabricating chips including the nonvolatile memory device 110 to evaluate the new algorithms.

According to various example embodiments, the storage device 100 including the ENC circuit 120 may receive control signals from the external device 200 and may apply the control signals to the nonvolatile memory device 110, and thus, new algorithms may be applied to the nonvolatile memory device 110 with a high degree of freedom. As a result, fabricating a new chip to which a new algorithm is applicable is not necessary every time an algorithm is newly developed. Instead, control signals for new algorithms may be applied to the storage device 100 including the nonvolatile memory device 110, and the new algorithms may be evaluated using the control signals. Afterward, only algorithms with good evaluation results (for example, algorithms A and G) may be selected, and then only the design and verification process may be performed on the selected algorithms, markedly reducing the design time. For example, according to various example embodiments, the storage device 100 may be used to evaluate more algorithms than before, and then design and verify algorithms selected through the evaluation. Therefore, design and verification time may be reduced, and product quality may be improved because it is possible to discover better algorithms that might not be found in the flow of development of the related art.

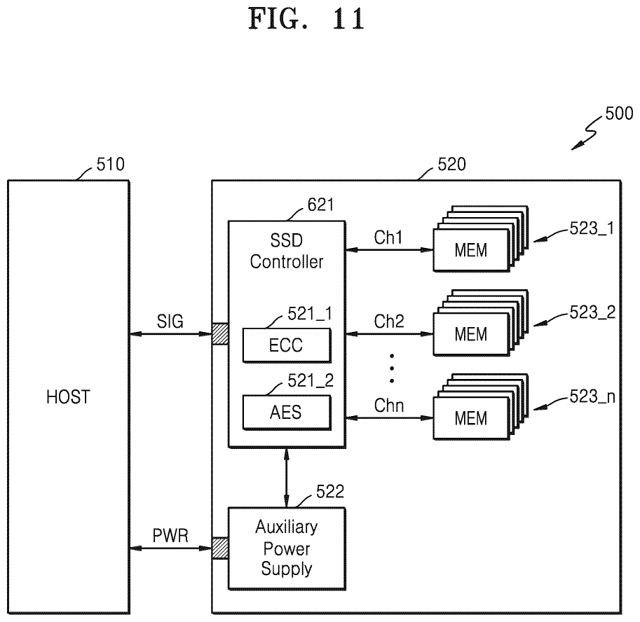

FIG. 11 is a block diagram illustrating an example of applying memory devices to a solid state drive (SSD) system 500 according to embodiments.

Referring to FIG. 11, the SSD system 500 may include a host 510 and an SSD 520. The SSD 520 may exchange signals SIG with the host 510 through a signal connector and receive power PWR through a power connector. The SSD 520 may include an SSD controller 621, an auxiliary power supply 522, and memory devices 523_1 to 523_n. The memory devices 523_1 to 523_n may be vertically stacked NAND flash memory devices. The SSD controller 621 may be connected to the memory devices 523_1 to 523_n through a plurality of channels Ch1 to Chn. In this case, each of the memory devices 523_1 to 523_n may be implemented using the embodiments described with reference to FIGS. 1 to 10.

The SSD controller 621 may include an error correction code (ECC) circuit 521_1 and an advanced encryption standard (AES) circuit 521_2. In addition, although not shown in FIG. 11, the SSD controller 621 may further include components such as a processor, a buffer, random access memory (RAM), a host interface, and a memory interface to control the overall operation of the SSD 520.

The ECC circuit 521_1 may perform ECC encoding and ECC decoding on data stored in or read from the memory devices 523_1 to 523_n. For example, the ECC circuit 521_1 may generate parity for error detection and correction when performing ECC encoding on write data, and perform error detection and correction operations based on data and parity read from the memory devices 523_1 to 523_n. In addition, the AES circuit 521_2 may perform at least one of encryption and decryption operations on data input/output to/from the SSD controller 621. The AES circuit 521_2 may perform encryption and decryption operations using various types of encryption/decryption algorithms (for example, a symmetric-key algorithm).

As described above, according to one or more of example embodiments described above, the storage device includes an ENC circuit configured to generate control signals based on data received from an external device without any limitations on the degree of freedom, and may thus evaluate the characteristics of memory cells in various manners.

Effects obtainable from the embodiments are not limited to the effects mentioned above, and other effects not mentioned above may be clearly derived and understood based on the description given herein by those of ordinary skill in the art to which the embodiments pertain. For example, unintended effects resulting from the implementation of the embodiments may also be derived by those of ordinary skill in the art from the embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

It should be understood that various example embodiments described herein should be considered in a descriptive sense only and not for purposes of limitation. Descriptions of features or aspects within each embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims.

What is claimed is:

1. A storage device comprising:
an external NAND control (ENC) circuit comprising a deserializer configured to deserialize data received from an external device, a buffer memory configured to store the data, and a data loader configured to generate a control signal based on the data; and
a nonvolatile memory device comprising a memory cell array, a voltage generator, a row decoder, and a page buffer,
wherein the data comprises control information associated with implementing a hardware algorithm.

2. The storage device of claim 1, wherein the hardware algorithm comprises at least information about a sequence of applying voltage to word lines and information about a step of voltage to be applied to the word lines.

3. The storage device of claim 1, wherein the deserializer is further configured to receive the data from the external device through N channels and to divide the data into M pieces per channel by deserializing the data into N×M channels.

4. The storage device of claim 3, wherein a clock frequency of data output to the buffer memory corresponds to a value obtained by dividing a clock frequency of data input to the deserializer by a number of the M pieces.

5. The storage device of claim 1, wherein the buffer memory corresponds to static random access memory (SRAM) comprising a plurality of bank memories.

6. The storage device of claim 5, wherein the plurality of bank memories comprise bank memories respectively corresponding to a plurality of channels and an additional bank memory configured to store duration information indicating a time period for each event.

7. The storage device of claim 1, wherein the data loader is further configured to:
receive, from the buffer memory, a first piece of duration information and a first piece of data, the first piece of data corresponding to a first event, and
repeatedly apply the first piece of data to the nonvolatile memory device for a time period indicated by the first piece of duration information.

8. A method of operating a storage device comprising an external NAND control (ENC) circuit configured to receive data from an external device, and a nonvolatile memory device, the method comprising:
receiving data from the external device;
dividing the received data into a plurality of channels;
storing the divided data in a buffer memory; and
acquiring memory cell characteristics by generating a control signal based on the divided data and applying the control signal to the nonvolatile memory device,
wherein the data comprises control information associated with implementing a hardware algorithm.

9. The method of claim 8, wherein the hardware algorithm comprises at least information about a sequence of applying voltage to word lines and information about a step of voltage to be applied to the word lines.

10. The method of claim 8, wherein a number of the plurality of channels is one less than a number of bank memories included in the buffer memory.

11. The method of claim 10, wherein a clock frequency output to the buffer memory corresponds to a value obtained by dividing a clock frequency input to a deserializer by the number of the plurality of channels.

12. The method of claim 8, wherein the buffer memory corresponds to static random access memory (SRAM) comprising a plurality of bank memories.

13. The method of claim 12, wherein the plurality of bank memories comprise bank memories respectively corresponding to the plurality of channels and an additional bank memory associated with storing duration information indicating a time period for each event.

14. The method of claim 8, wherein the generating of the control signal based on the divided data comprises:
reading, from the buffer memory, a first piece of duration information and a first piece of data, the first piece of data corresponding to a first event; and
repeatedly applying the first piece of data to the nonvolatile memory device for a time period indicated by the first piece of duration information.

15. A memory system comprising an external device and a storage device,
wherein the external device is configured to provide the storage device with data associated with identifying memory cell characteristics of the storage device,
wherein the storage device comprises an extended NAND control (ENC) circuit and a nonvolatile memory device, the ENC circuit comprising a deserializer configured to deserialize the data received from the external device, a buffer memory configured to store the data, and a data loader configured to generate a control signal based on the data, the nonvolatile memory device comprising a memory cell array,
wherein the data comprises control information associated with implementing a hardware algorithm.

16. The memory system of claim 15, wherein the external device comprises a field programmable gate array (FPGA).

17. The memory system of claim 15, wherein the hardware algorithm comprises at least information about a sequence of applying voltage to word lines and information about a step of voltage to be applied to the word lines.

18. The memory system of claim 15, wherein
the buffer memory corresponds to static random access memory (SRAM) comprising a plurality of bank memories, and
the deserializer is further configured to receive the data from the external device through N channels and to divide the data into M pieces per channel by deserializing the data into N×M channels.

19. The memory system of claim 18, wherein the plurality of bank memories comprise bank memories respectively corresponding to a plurality of channels and an additional bank memory for storing duration information indicating a time period for each event.

20. The memory system of claim 15, wherein the data loader is further configured to:
receive, from the buffer memory, a first piece of duration information and a first piece of data, the first piece of data corresponding to a first event; and
repeatedly apply the first piece of data to the nonvolatile memory device for a time period indicated by the first piece of duration information.
